(19) United States
(12) Patent Application Publication
(10) Pub. No.: US 2014/0164862 A1
(43) Pub. Date: Jun. 12, 2014

(54) ELECTRONIC DEVICE TESTING SYSTEM AND METHOD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: KANG-BIN WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/949,191

(22) Filed: Jul. 23, 2013

(30) Foreign Application Priority Data
Dec. 11, 2012 (CN) 2012105304042

(51) Int. Cl. G01R 31/3177

(52) U.S. Cl. CPC G01R 31/3177
USPC 714/736

(57) ABSTRACT

An electronic device testing system is configured to test an electronic device which generates a plurality of signals while running. The electronic device testing system includes a programmable logic device (PLD) configured to monitor and control the electronic device and a computer connected to the PLD. The PLD includes a read/write control module connected to the electronic device and a controller connected to the read/write control module. The read/write control module reads the plurality of signals generated by the electronic device. The controller determines whether the plurality of signals has errors and sends error signals to the computer. The computer analyzes the error signals and displays problems associated with the error signals. The present disclosure further discloses an electronic device testing method based upon the above testing system.

### BACKGROUND

1. Technical Field

The present disclosure relates to an electronic device testing system and method.

2. Description of Related Art

After an electronic device, such as a server computer, is manufactured, operators have to test whether signals generated by the electronic device conforms to predetermined values. However, operators have to utilize test tools, such as an oscilloscope and an analyzing apparatus, to test the signals, which is inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an electronic device testing system according to an embodiment.

FIG. 2 is a flow chart of an electronic device testing method according to an embodiment.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean “at least one.”

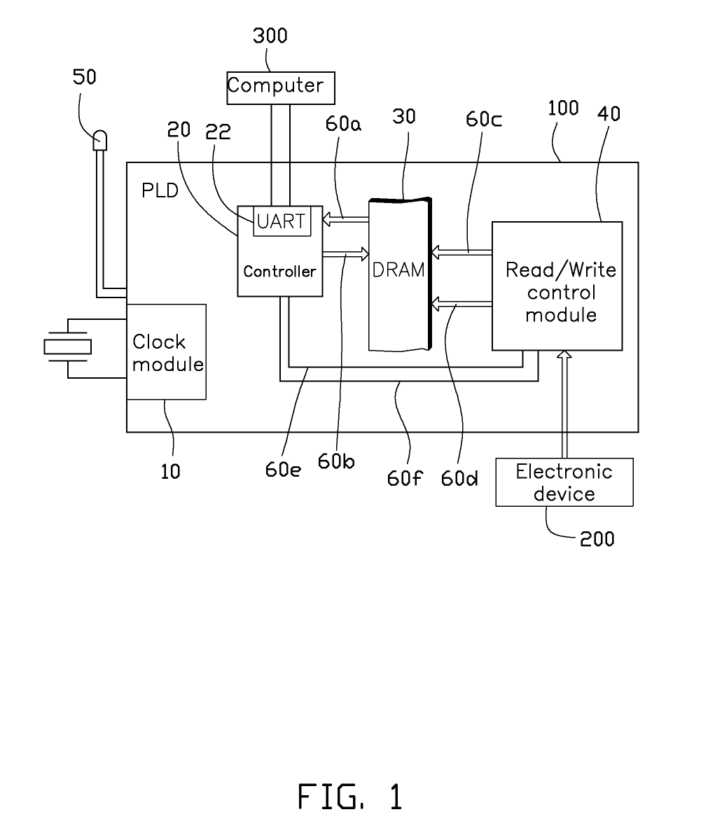

FIG. 1 shows an embodiment of a testing system for testing an electronic device 200 comprising a programmable logic device (PLD) 100 and a computer 300 connected to the PLD 100. The PLD 100 can monitor the electronic device 200 and receives signals generated by the electronic device 200. The PLD 100 can also determine whether there an error signal generated by the electronic device 200 and send the error signal to the computer 300. The computer 300 analyzes the error signal and indicates the reason for the error. In one embodiment, the PLD 100 is a complex programmable logic device (CPLD). The electronic device 200 is a server.

The PLD 100 includes a clock module 10, a controller 20, a Dynamic Random Access Memory (DRAM) 30, and a read/write control module 40. The clock module 10 is connected to a crystal oscillator for generating clock signals for the PLD 100. The controller 20 includes a Universal Asynchronous Receiver/Transmitter (UART) interface 22 connected to the computer 300. The controller 20 is connected to the DRAM 30 via a first data bus 60a and a first address bus 60b. The DRAM 30 is connected to the read/write control module 40 via a second data bus 60c and a second address bus 60d. The controller 20 is connected to the read/write control module 40 via a first connection 60e and a second connection 60f. The controller 20 can send a read enable signal to the read/write control module 40 via the second connection 60f. The read/write control module 40 reads signals from the electronic device 200 after receiving the read enable signal. The read/write control module 40 can send a notification signal to the controller 20 via the first connection 60e when the read/write control module 40 has written data into the DRAM 30. An indicating lamp 50 is connected to the PLD 100 to indicate whether the PLD 100 detects any error signal.

When the testing system is working, the controller 20 sends the read enable signal to the read/write control module 40. The read/write control module 40 reads signals generated by the electronic device 200. The read/write control module 40 writes information of the signals into the DRAM 30 and sends the notification signal to the controller 20. The controller 20 analyzes whether there is an error in the information written in the DRAM 30. If there is an error, the controller 20 sends the error information to the computer 300 and switches on the indicating lamp 50. The computer 300 analyzes the error information and indicates the reason for the error. If there is not any error, the controller 20 switches off the indicating lamp 50.

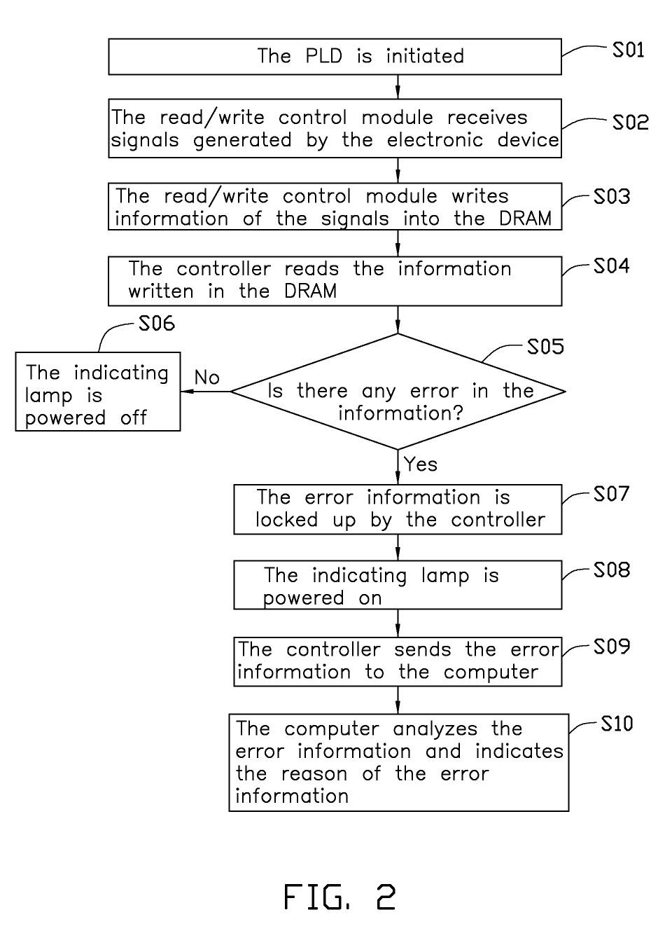

FIG. 2 shows a flow chart of a testing method based upon the above testing system. The testing method includes following blocks.

In block S01, the PLD 100 is initiated.

In block S02, the read/write control module 40 receives signals generated by the electronic device 200.

In block S03, the read/write control module 40 writes information of the signals generated by the electronic device 200 into the DRAM 30.

In block S04, the controller 20 reads the information written in the DRAM 30.

In block S05, the controller 20 determines whether there is an error in the information. If there is no error, go to block S06; if there is an error in the signals generated by the electronic device 200, go to block S07.

In block S06, the indicating lamp 50 is powered off to indicate there is no error detected by the PLD 100.

In block S07, the error information is locked up by the controller 20.

In block S08, the indicating lamp 50 is powered on to indicate one or more errors are detected by the PLD 100.

In block S09, the controller 20 sends the error information to the computer 300.

In block S10, the computer 300 analyzes the error information and indicates the reason of the error information.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

Depending on the embodiment, certain of the steps of methods described may be removed, others may be added, and the sequence of steps may be altered. It is also to be understood that the description and the claims drawn to a method may include some indication in reference to certain steps. However, any indication used is only to be viewed for identification purposes and not as a suggestion as to an order for the steps.

What is claimed is:

1. A system for testing an electronic device generating a plurality of signals during running, comprising:
a programmable logic device (PLD) configured to monitor and control the electronic device; the PLD comprising a read/write control module connected to the electronic device and a controller connected to the read/write control module; and
a computer connected to the PLD;
wherein the read/write control module is capable of reading the plurality of signals generated by the electronic device, and the controller is capable of determining whether there is any error in the plurality of signals and sends error signal to the computer; and the computer is capable of analyzing the error signal and indicating reasons for the error signal.

2. The system of claim 1, further comprising an indicating lamp connected to the PLD, wherein the indicating lamp is powered on when the plurality of signals has the error signal and the indicating lamp is powered off if the plurality of signals does not have the error signal.

3. The system of claim 2, wherein the PLD further comprises a memory connected to the controller and the read/write control module, the read/write control module is capable of writing data indicative of the plurality of signals into the memory, and the controller is capable of reading the data from the memory.

4. The system of claim 3, wherein the controller is connected to the memory via a first data bus and a first address bus; and the memory is connected to the read/write control module via a second data bus and a second address bus.

5. The system of claim 4, wherein the controller is connected to the read/write control module via a first connection and a second connection; the controller is capable of sending read enable signals to the read/write control module via the second connection;
and the read/write control module is capable of sending a notification signal to the controller via the first connection when the data is written in the memory by the read/write control module.

6. The system of claim 1, wherein the controller comprises a Universal Asynchronous Receiver/Transmitter interface connected to the computer.

7. A method for testing an electronic device generating a plurality of signals during running, comprising:
providing a programmable logic device (PLD) which comprises a read/write control module and a controller connected to the read/write control module;
the read/write control module reading the plurality of signals from the electronic device;
determining whether there is any error signal existing in the plurality of signals;
sending error signal to a computer when the plurality of signals has error signal; and
the computer analyzing the error signal and indicating reasons for the error signal.

8. The method of claim 7, further comprising powering on an indicating lamp when the plurality of signals has the error signal.

9. The method of claim 7, further comprising locking the error signal by the controller before sending the error signal to the computer.

10. The method of claim 7, further comprising writing information of the plurality of signals into a memory after reading the plurality of signals.

11. The method of claim 10, further comprising sending a notification signal to the controller when data indicative of the plurality of signals is written into the memory.

12. The method of claim 7, further comprising sending a read enable signal to the read/write control module before reading the plurality of signals.
